(19) United States
(12) Patent Application Publication
(10) Pub. No.: US 2020/0042466 A1
(43) Pub. Date: Feb. 6, 2020

(54) Power Loss Protection And Recovery

(71) Applicant: Burlywood, Inc., Longmont, CO (US)

(72) Inventors: Amy Lee Wohlschlegel, Lafayette, CO (US); Kevin Darveau Landin, Longmont, CO (US); Nathan Koch, Longmont, CO (US); John William Slattery, Boulder, CO (US); Erik Habbinga, Fort Collins, CO (US)

(73) Assignee: Burlywood, Inc., Longmont, CO (US)

(21) Appl. No.: 16/530,567

(22) Filed: Aug. 2, 2019

Related U.S. Application Data
(60) Provisional application No. 62/714,518, filed on Aug. 3, 2018.

(51) Int. Cl. G06F 12/16; G11C 5/00; G06F 1/30; G06F 11/14; G06F 12/02

(52) U.S. Cl. CPC G06F 12/16; G11C 5/005; G06F 12/0246; G06F 11/1441; G06F 1/30

(57) ABSTRACT

A method of operating a data storage system is provided. The method includes establishing a user region on a non-volatile storage media of the data storage system configured to store user data, and establishing a recovery region on the non-volatile storage media of the data storage system configured to store recovery information pertaining to at least the user region. The method also includes updating the recovery information in the recovery region responsive to at least changes to the user region, and responsive to at least a power interruption of the data storage system, rebuilding at least a portion of the user region using the recovery information retrieved from the recovery region.

### RELATED APPLICATIONS

This application hereby claims the benefit of and priority to U.S. Provisional Patent Application No. 62/714,518, titled “POWER LOSS PROTECTION AND RECOVERY”, filed on Aug. 3, 2018 and which is hereby incorporated by reference in its entirety.

### TECHNICAL FIELD

Aspects of the disclosure are related to data storage and in particular to protection and recovery from power loss.

### TECHNICAL BACKGROUND

Making data written to a drive safe from an unexpected power loss is a complicated problem. Solutions often introduce further issues, such as negative effects on Quality of Service (QoS) and performance, as well as introducing further complexity into both the performance path and the system as a whole. Recovery typically requires relating physical scans back to logical mappings of data. Some solutions have many corner cases, high complexity, and require special algorithms separate from those used for user data to read, write, and garbage collect table data, as well as perform error handling on the table data. Some solutions also tend to rely on capacitors to keep powering the drive for a short time in order to write some emergency table data out to non-volatile memory (NVM).

### OVERVIEW

In an embodiment, a method of operating a data storage system is provided. The method includes establishing a user region on a non-volatile storage media of the data storage system configured to store user data, and establishing a recovery region on the non-volatile storage media of the data storage system configured to store recovery information pertaining to at least the user region. The method also includes updating the recovery information in the recovery region responsive to at least changes to the user region, and responsive to at least a power interruption of the data storage system, rebuilding at least a portion of the user region using the recovery information retrieved from the recovery region.

In another embodiment, a storage controller for a storage system is provided. The storage controller includes a host interface, configured to receive host data for storage within the storage system, a storage interface, configured to transmit storage data to the storage system, and processing circuitry coupled with the host interface and the storage interface.

The processing circuitry is configured to establish a user region on a non-volatile storage media of the data storage system configured to store user data, and to establish a recovery region on the non-volatile storage media of the data storage system configured to store recovery information pertaining to at least the user region. The processing circuitry is further configured to update the recovery information in the recovery region responsive to at least changes to the user region, and responsive to at least a power interruption of the data storage system, to rebuild at least a portion of the user region using the recovery information retrieved from the recovery region.

In a further embodiment, one or more non-transitory computer-readable media having stored thereon program instructions to operate a storage controller for a storage system are provided. The program instructions, when executed by processing circuitry, direct the processing circuitry to at least establish a user region on a non-volatile storage media of the data storage system configured to store user data, and to establish a recovery region on the non-volatile storage media of the data storage system configured to store recovery information pertaining to at least the user region.

The program instructions, when executed by the processing circuitry, further direct the processing circuitry to at least update the recovery information in the recovery region responsive to at least changes to the user region, and responsive to at least a power interruption of the data storage system, to rebuild at least a portion of the user region using the recovery information retrieved from the recovery region.

### BRIEF DESCRIPTION OF THE DRAWINGS

Many aspects of the disclosure can be better understood with reference to the following drawings. While several implementations are described in connection with these drawings, the disclosure is not limited to the implementations disclosed herein. On the contrary, the intent is to cover all alternatives, modifications, and equivalents.

FIG. 1 illustrates a computer host and data storage system.

FIG. 2 illustrates an example embodiment of a data storage system.

FIG. 3 illustrates an example of data block address offset scanning.

FIG. 4 illustrates an example of data storage cell organization.

FIG. 5 illustrates an example media management table recovery operation on the recovery region.

FIG. 6A illustrates an example embodiment having larger data blocks.

FIG. 6B illustrates an example embodiment having smaller data blocks.

FIG. 7 illustrates an example method for power loss recovery.

FIG. 8 illustrates a storage controller.

### DETAILED DESCRIPTION

The example embodiments described herein reduce complexity and corner cases during both runtime and recovery as well as the error handling on writing and reading table data by utilizing the existing media management layer to manage both the user data as well as the table data instead of having a separate solution for each. The media management layer is a layer of software with knowledge of how data needs to be written to non-volatile media, ensures that media wears evenly, handles defects, and provides error correction capabilities. The examples herein also reduce the overall area of non-volatile memory (NVM) that needs to be scanned. The examples herein also are designed so that no extra table data (all host management and media management tables) needs to be written out at the time of power loss, thereby eliminating the need for hold up capacitors.

The following description assumes that the media being managed by the media management layer is NAND flash for purposes of illustration. It should be understood that the examples below can be applied to other types of storage media, such as magnetic random-access memory, phase change memory, memristor memory, among others.

Flash media is usually managed by writing to groups of blocks, sometimes known as superblocks or block stripes. Part of the job of the media management layer is to track the state of the blocks and block stripes and recover the state of all blocks and block stripes if a sudden power loss occurs.

Many of the advantages of the examples discussed herein rely on the use of a data block address (DBA) based read and write path for both the user data and the table data. Data block addresses are always increasing numbers that identify a data block in the order that it was written within a region of memory. Rather than mapping host block addresses (HBAs) (such as sector numbers) directly to the flash, there is an additional mapping from host block address to data block address, then from data block address to flash address.

Although at first glance, adding another mapping seems like a disadvantage, it has advantages that outweigh the additional mapping, especially when it comes to power loss recovery. One advantage is that given a physical geometry of a block stripe (flash media is usually managed by writing to groups of blocks, know as superblocks or block stripes) and a start data block address of that block stripe, the flash address of any data block address in that stripe can be computed. However, when a start data block address is not known, it can still be easily determined using the same computation, but viewing each data block address in the stripe as a data block address offset, rather than a unique data block address. This allows for logical based scanning of physical flash, before any mapping data has been recovered.

The example embodiments illustrated herein logically write table data and logs of changes to table data, using data block addresses, to a reserved region of non-volatile memory. For particular types of table data, the data is written in a manner that no table change is considered complete until the log recording the change/action has been successfully written to the non-volatile memory. This ensures that without any capacitor hold up, all tables can be fully rebuilt.

Writing the data in logical pieces, using data block addresses, enables the utilization of the same code used to read from and write to the user region to also read and write the table data, or easily change the type of media to which the table data is written. The particular type of table data which might wait for successful writing of the log to the non-volatile memory before changes are considered complete include media management tables. Other tables, such as host management tables, do not need to wait for successful writing of the log to the non-volatile memory. The example embodiments illustrated herein also minimize the complexity of rebuilding this data by using logical offset based scans rather than physical scans, while also reducing the amount of the non-volatile memory that needs to be scanned at all. As will be discussed below, the address of any data block can be computed given a physical geometry of a stripe and a start data block address.

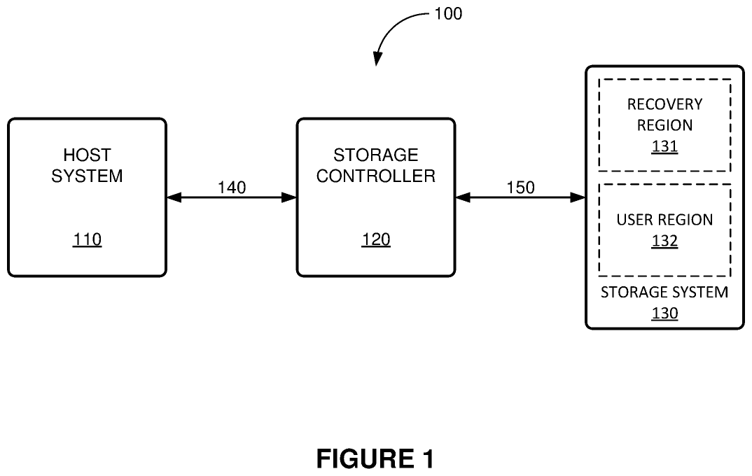

FIG. 1 illustrates computer host and data storage system 100. In this example embodiment, host system 110 sends data to, and receives data from, storage controller 120 for storage in storage system 130. In an example embodiment, storage system 130 comprises flash non-volatile memory, such as NAND memory. NAND memory is just one example, other embodiments of storage system 130 may comprise other types of storage. The storage media can be any non-volatile memory, such as a flash memory, magnetic random-access memory, phase change memory, optical or magnetic memory, solid-state memory, or other forms of non-volatile memory devices.

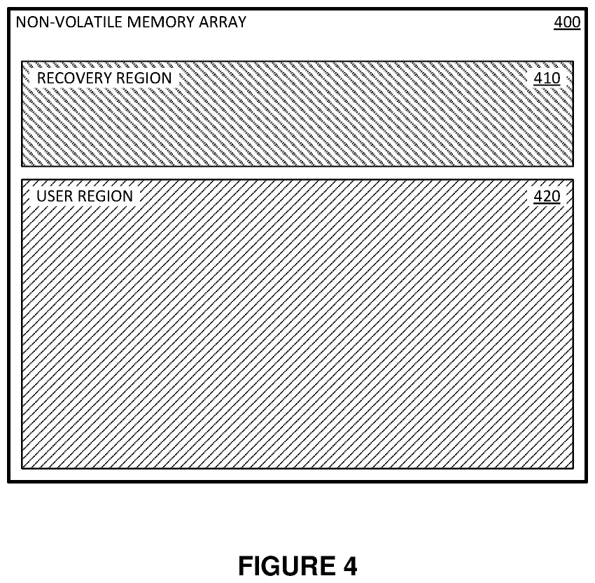

Storage controller 120 communicates with storage system over link 150, and performs the function of configuring data received from host system 110 into a format that efficiently uses the memory resources of storage system 130. In this example embodiment, storage system 130 includes recovery region 131 and user region 132. These regions are discussed in detail below with respect to FIG. 4.

Storage controller 120 provides translation between standard storage interfaces and command protocols used by host system 110 to a command protocol and the physical interface used by storage devices within storage system 130. Additionally, storage controller 120 implements error correction code (ECC) encode/decode functions, along with data encoding, data recovery, retry recovery methods, and other processes and methods to optimize data integrity.

Storage controller 120 may take any of a variety of configurations. In some examples, storage controller 120 may be a Field Programmable Gate Array (FPGA) with software, software with a memory buffer, an Application Specific Integrated Circuit (ASIC) designed to be included in a single module with storage system 130, a set of Hardware Description Language (HDL) commands, such as Verilog or System Verilog, used to create an ASIC, a separate module from storage system 130, built in to storage system 130, or any of many other possible configurations.

Host system 110 communicates with storage controller 120 over various communication links, such as communication link 140. These communication links may use the Internet or other global communication networks. Each communication link may comprise one or more wireless links that can each further include Long Term Evolution (LTE), Global System For Mobile Communications (GSM), Code Division Multiple Access (CDMA), IEEE 802.11 WiFi, Bluetooth, Personal Area Networks (PANs), Wide Area Networks, (WANs), Local Area Networks (LANs), or Wireless Local Area Networks (WLANs), including combinations, variations, and improvements thereof. These communication links can carry any communication protocol suitable for wireless communications, such as Internet Protocol (IP) or Ethernet.

Additionally, communication links can include one or more wired portions which can comprise synchronous optical networking (SONET), hybrid fiber-coax (HFC), Time Division Multiplex (TDM), asynchronous transfer mode (ATM), circuit-switched, communication signaling, or some other communication signaling, including combinations, variations or improvements thereof. Communication links can each use metal, glass, optical, air, space, or some other material as the transport media. Communication links may each be a direct link, or may include intermediate networks, systems, or devices, and may include a logical network link transported over multiple physical links.

Storage controller 120 communicates with storage system 130 over link 150. Link 150 may be any interface to a storage device or array. In one example, storage system 130 comprises NAND flash memory and link 150 may use the Open NAND Flash Interface (ONFI) command protocol, or the “Toggle” command protocol to communicate between storage controller 120 and storage system 130. Other embodiments may use other types of memory and other command protocols. Other common low level storage interfaces include DRAM memory bus, SRAM memory bus, and SPI.

Link 150 can also be a higher level storage interface such as SAS, SATA, PCIe, Ethernet, Fiber Channel, Infiniband, and the like. However—in these cases, storage controller 120 would reside in storage system 130 as it has its own controller.

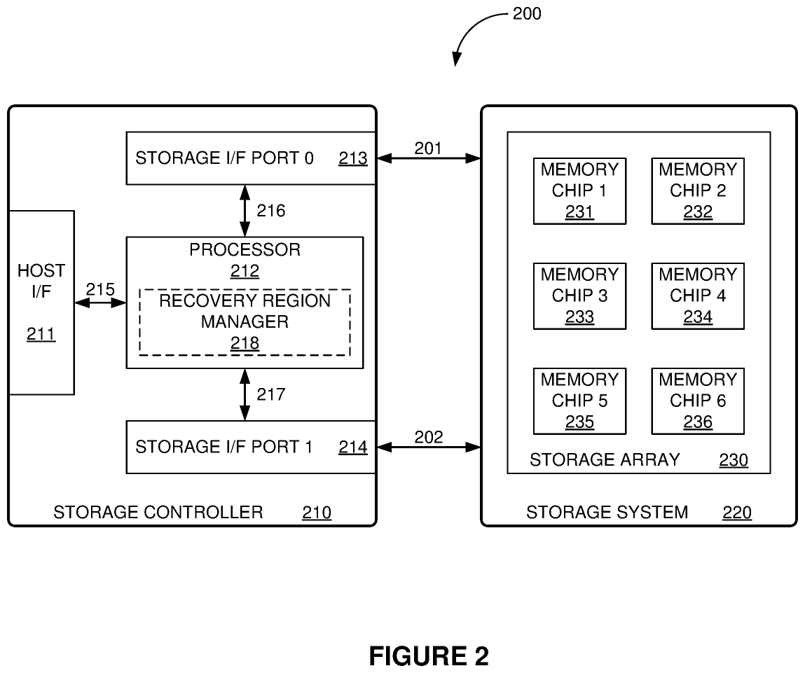

FIG. 2 illustrates data storage system 200. This example system comprises storage controller 210 and storage system 220. Storage system 220, comprises storage array 230. Storage array 230 comprises memory chips 1-6 (231-236).

In an example embodiment, each memory chip 231-236 is a NAND memory integrated circuit. Other embodiments may use other types of memory. The storage media can be any non-volatile memory, such as a flash memory, magnetic random-access memory, phase change memory, optical or magnetic memory, solid-state memory, or other forms of non-volatile memory devices. In this example, storage array 230 is partitioned into a user region and a recovery region. These regions are partitioned physically on storage array 230 so that the two regions do not share any memory blocks, ensuring that each physical location on storage array 230 only belongs to one region, as illustrated in FIG. 4.

Storage controller 210 comprises a number of blocks or modules including host interface 211, processor 212 (including recovery region manager 218), storage interface port 0 213, and storage interface port 1 214. Processor 212 communicates with the other blocks over links 215, 216, and 217. Storage interface port 0 213 communicates with storage system 220 over link 201 and storage interface port 1 214 communicates with storage system 220 over link 202.

In some example embodiments, storage interface ports 0 and 1 (213 and 214) may use the Open NAND Flash Interface (ONFI) command protocol, or the “Toggle” command protocol to communicate with storage system 220 over links 201 and 201. The ONFI specification includes both the physical interface and the command protocol of ONFI ports 0 and 1. The interface includes an 8-bit bus (in links 201 and 202) and enables storage controller 210 to perform read, program, erase, and other associated operations to operate memory chips 1-6 (231-236) within storage array 230.

Multiple memory chips may share each ONFI bus, however individual memory chips may not share multiple ONFI buses. Chips on one bus may only communicate with that bus. For example, memory chips 1-3 (231-233) may reside on bus 201, and memory chips 4-6 (234-236) may reside on bus 202.

In this example, processor 212 receives host data from a host through host interface 211 over link 215. Processor 212 configures the data as needed for storage in storage system 220 and transfers the data to storage interface ports 0 and 1 (213 and 214) for transfer to storage system 220 over links 201 and 202.

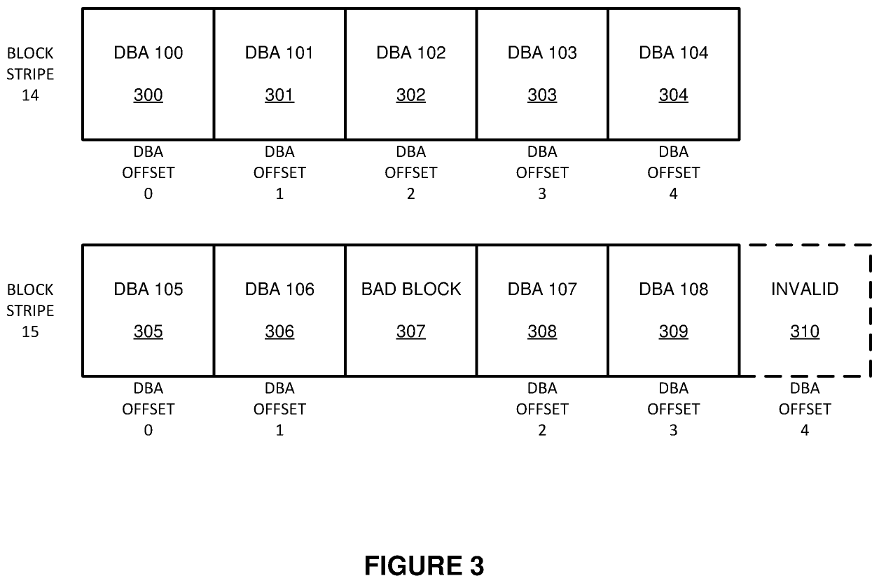

In this example, recovery region manager 218 is implemented as part of processor 212 and is configured to use a recovery region within storage array 230 to recover from power failures as illustrated in FIGS. 3-6 and described in detail below.

FIG. 3 illustrates an example of data block address offset scanning. In this example embodiment each block stripe can be viewed as a sequence of data block addresses, or alternatively as a sequence of data block address offsets. Data block addresses are used when the start data block address is known, but data block address offsets can be used when the start data block address is not yet known.

In this example, block stripe 14 includes five data blocks 300-304 having data block addresses 100-104 and data block address offsets 0-4 respectively.

Given the physical geometry of a block stripe, it can be determined how many data block addresses would fit in a “perfect” block stripe (one that has no bad blocks). That number can be used as a baseline for how many data block address offsets to attempt to read during a recovery scan, such as shown in block stripe 14 in FIG. 3.

Then when a data block address offset that goes past the end of the block stripe is attempted to be read, the computation will return an error, and this will notify the scan that it has completed the block stripe. This is illustrated in FIG. 3, with block stripe 15, data block address offset 4. In this example block stripe 15 includes four data blocks 305, 306, 308, and 309 having data block addresses 105-108 and data block address offsets 0-3 respectively. Here block stripe 15 also includes bad block 307. When this block stripe is attempted to be read using data block address offsets, invalid block 310 is attempted to be read by data block address offset 4, and since invalid block 310 doesn't exist the computation returns an error.

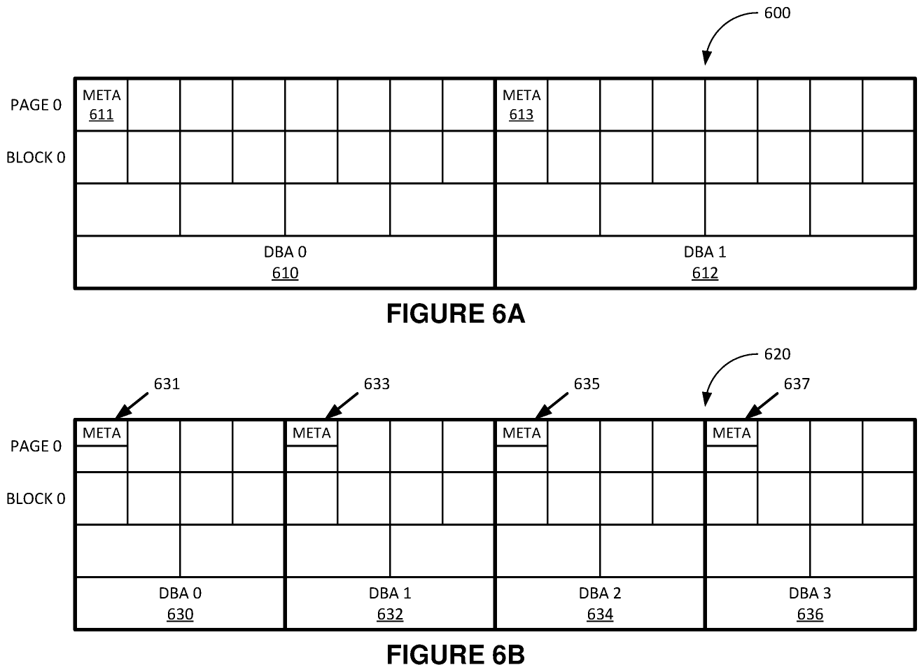

Another advantage of the data block address, is that the size can be adjusted to optimize for the underlying non-volatile memory, or to minimize or reduce the scan time. For example, when data block addresses are mapped to flash memory, the data block address size could be adjusted in order to map to the optimal write size. When data block address size is chosen to optimize for scan time, data block address size can be increased to be a multiple of the optimal write size so that just one page read of flash memory recovers the most metadata. Therefore, this operation can reduce the amount of flash memory that needs to be scanned during power loss recovery. Metadata scan processes and data block size tuning are illustrated in FIGS. 6A and 6B and discussed in detail below.

FIG. 4 illustrates an example of data storage cell organization. NAND flash non-volatile storage systems are organized as an array of memory cells surrounded by control logic to allow it to be programmed, read, and erased. The cells in a typical flash array are organized in pages for program and read operations. Multiple pages are in a data block and usually must be written sequentially within a data block. Erase operations are done on a data block basis.

In this example, non-volatile memory array 400, such as storage array 230 from FIG. 2, includes a recovery region 410 and a user region 420. User region 420 stores user data, and recovery region 410 stores table data. In an example, these regions are partitioned physically on the flash so that regions do not share any flash blocks, ensuring that each physical location on the flash only belongs to one region. Media management tables are created, and are used to determine where a given data block address is physically located on the flash within the user region. This table data is stored in the recovery region.

Although having table data physically separated on the flash media 400 from user data 420 might be encountered in some other implementations, these implementations typically manage table data differently than user data. A typical solution would be to store the physical flash address of the start of the table data.

The examples discussed herein allow table data to be written in logical chunks (data blocks) in a similar way that data is written in a user region. This allows for shared mechanisms and shared code for reading and writing to both a user region and a recovery region. In such examples, recovery region 410 might have its own set of tables similar to those used for the user region. The data is typically written one data block address at a time, ensuring a previous data block address is fully written before attempting to write another.

When a clean shutdown sequence is followed, table data for recovery region 410 can be stored in another region of non-volatile memory array 400, which may or may not be different from the main flash storage of the drive, such as NOR or EMMC media. However, table data can also be rebuilt following an unexpected power loss. To aid the rebuild of the table data for the recovery region, the data written into the recovery region is self-describing.

In an example, the recovery region is configured in a way that block stripes are always formed similarly. After an unexpected power loss, recovery region 410 requires more per-block recovery effort than user region 420. However, recovery region 410 will be significantly smaller than user region 420, thus providing for overall less recovery effort. This resultant effort level is used to optimize the size of recovery region 420. In an example, recovery region 420 is sized by balancing life cycle requirements, table data sizes, effect on QoS, and recovery time requirements, among other factors. In the examples herein, the data is written logically and is read and written using similar mechanisms as are used to read and write data with regard to user region 420. This operation greatly simplify steps for recovery, reduces firmware code space requirements, and reduces the amount of firmware that needs to be developed, tested, and maintained.

Recovery region 410, as illustrated in FIG. 4, contains both full snapshots of the media management tables for user region 420 as well as logs indicating changes to the media management tables for user region 420. In an example, full snapshots are written at opportune moments, such as following a successful recovery, or during a clean shutdown sequence. In some embodiments, these full snapshots are also written when the recovery region is approaching a capacity limit to contain additional change logs.

In an example embodiment, the size of recovery region 410 is selected to account for an optimal capacity limit to contain logs. Writing a full snapshot while user data is concurrently being written to the flash media can have negative effects on performance and QoS, in part because the writes to recovery region 410 consume bandwidth on the flash media 230 as well as processor usage of the storage drive.

However, when a cadence and frequency of the snapshot writes are tuned correctly, negative effects on bandwidth and processor usage is negligible. For example, writing one data block address at a time and minimizing the frequency at which the full snapshots are required helps to reduce effects on performance and latency. Writing a full snapshot can block further block stripe state changes from occurring until the snapshot completes. Thus, state changes can be performed enough in advance that user data throughput is not blocked by a block stripe state change.

In some examples, a full snapshot is written after both clean and dirty shutdown recoveries. This ensures that after a power cycle, the tables always start in a ‘clean’ state in recovery region 410. Then, each time an important block stripe change occurs, a log about that change is written to recovery region 410 before the block stripe can be used in that state. An important block stripe state change might be one that must be “power safe” in order to properly recover from an unexpected power loss once the block stripe is actually used in that state. However, before the block stripe is actually used in that state, the state change can still be lost or forgotten without consequences.

An example of this type of state change would be allowing a block stripe to be written to—often referred to as ‘opening’ a block stripe. This state change should be logged because, prior to this log, the block stripe is erased. If the log indicating to open the block stripe is lost before the block stripe is written to, then the block stripe remains erased. Therefore, the block stripe still contains no valid data, and no data is affected by losing that state change. However, if any data is already written the block stripe, it is important to know that the block stripe could contain valid data in order to make sure it gets mapped after an unexpected power loss.

A log to open a block stripe is also an example of ensuring this log occurs early enough that no user data throughput is blocked by this state change. Since no data can be written to the block stripe being opened until the log is fully written, there is a possibility of blocking occurring to data operations. To avoid this situation, block stripes can be pre-opened while there is still enough room left in the current open block stripe to ensure that the current open block stripe will not fill up before the log to open the next one can complete.

A log pertaining to a block stripe state change should contain all data necessary to quickly ‘re-play’ the state change. For example, when a block stripe becomes fully written, the log should include the new block stripe state, the blocks that block stripe is made up of, and the mapping of what data block addresses reside in that block stripe.

To recover the tables for recovery region 410, a series of recovery region scans are employed. As discussed above, recovery region 410 can be physically partitioned on the flash media, and the whole recovery region 410 can further be broken into block stripes.

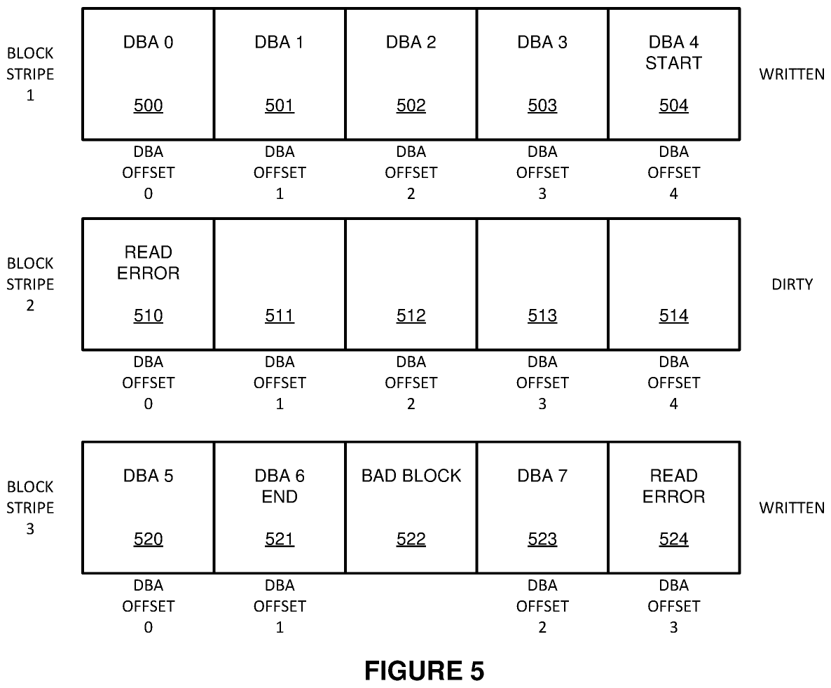

FIG. 5 illustrates an example media management table recovery operation on the recovery region. A first recovery region scan reads a first data block address (DBA) offset of each block stripe. In FIG. 5, this corresponds to reading data block address offset 0 of block stripes 1, 2, and 3. For each block stripe, if the first offset reads successfully without a read error, then the block stripe is considered written. The term “written” in this context indicates that the particular block stripe could contain valid recovery data. If the first offset fails to read successfully, the block stripe is considered dirty. The term “dirty” in this context indicates that the particular block stripe does not contain valid recovery data. The read to the first data block address offset can thus distinguish between written and dirty states.

In this example, block stripe 1 is “written” and includes data blocks 500-504 having data block addresses 0-4 and data block address offsets 0-4 respectively. Block stripe 2 containing data blocks 510-514 is “dirty” since an attempted read of data block 510 at data block address offset 0 results in a read error. Block stripe 3 includes data blocks 520-524. Data block 520 has a data block address of 5 and is at data block address offset 0, data block 521 has a data block address of 6 and is at data block address offset 1, data block 522 is a bad block, data block 523 has a data block address of 7 and is at data block address offset 3, data block 524 is at data block address offset 3 and returns a read error. Block stripe 3 is “written” even though it includes bad block 522 and generates a read error for data block 524 at data block address offset 3.

Each time a data block is written to the recovery region, the data block write is completed before another data block write is attempted. Each data block includes metadata that indicates a data block address number of that data block. Data block address numbers are configured to be always sequential and represent an order written. The data block address of each successful read from the first data block address offset in a block stripe is noted. Then, the written block stripes are sorted into the order originally written. In FIG. 5, after the first recovery region scan, block stripes 1 and 3 are determined to potentially contain valid data, and the first data block addresses in those block stripes are DBA 0 and DBA 5, respectively. This completes the first recovery region scan.

A second recovery region scan reads each data block address offset in the written block stripes to determine where the most recent user region table data resides. The data block addresses are read in the same order as written by again utilizing an offset-based data block address read. Each physical location of a data block in a block stripe can be determined given a data block address offset into the block stripe. Then, as the data block addresses are read, the discovered start and end of the table data can be noted. Once all written block stripes have been scanned, the most recent full table snapshot start and end are known. Referring back to the example in FIG. 5, results from a second scan would have determined each written data block address number. The second scan would have also determined the most recent full table snapshot is contained at DBAs 4 through 6 504, 520, and 521, and the last data block written in the recovery region is at DBA 7 523.

After these scans are complete, the media management tables for the user region can be read using the data block addresses discovered during the scans. A full snapshot is read first, followed by any change logs that are found after that. In FIG. 5, there would be just one log at DBA 7 523. The full snapshot would be restored, and then the logs of block stripe state changes and data block address map changes can be ‘re-played’ on top of the baseline of the restored snapshot. At this point, states of all block stripes in the user region are known.

Any stripes left open at the time of power loss are missing associated table data, so it is restored using a data block address offset scan much like the one used for written stripes in the recovery region. However, since user data is not written one at a time, the scan accounts for possible holes that could be found in the open stripe. Once the scan of open block stripes in the user region is complete, all media management tables are recovered, and a new, clean, full snapshot is written to recovery region 410. All old power loss affected data is then trimmed.

Once media management tables are recovered, the media management layer is fully operational and the host management tables can be recovered by utilizing the normal read and write flow. By using the already rebuilt media management tables, data block addresses are read, and using a second layer of metadata, the host block addresses that reside in the data block addresses can be determined and added to the host management tables. This approach adds in more scanning, but eliminates the need to journal host writes and the complexities that come with that, such as managing where the journals are located and garbage collecting those journals.

This increase in scanning is manageable by tuning the data block size, as discussed briefly in an earlier section. As FIGS. 6A and 6B illustrate, various example embodiments tune the data block size to span a larger or smaller area of flash, depending on the runtime and recovery time requirements. FIG. 6A illustrates an example embodiment having larger data blocks. FIG. 6B illustrates an example embodiment having smaller data blocks. FIG. 6A illustrates two large example data blocks 610 and 612 having data block address 0 and 1 respectively. FIG. 6B illustrates four smaller example data blocks 630, 632, 624, and 636 having data block addresses 0-3 respectively.

In this example, data block size is selected in order to reduce the time needed to do a scan of user region 420 to recover host management tables. To speed up recovery time, a larger data block may be used in order to maximize a one-page flash read, sizing the data block so that the metadata that needs to be read to rebuild the table may consume the first page of the data block, as illustrated in FIG. 6A, where data block 610 includes metadata 611 and data block 612 includes metadata 613. This means that only one page per data block needs to actually be read in order to rebuild the host management tables, enabling the ability to scan the entire valid data block address space in a reasonable time for power loss recovery.

However, if this data block size is not optimal for runtime, it could be sized to span a smaller area of the flash, but with the cost of reducing the amount of metadata recovery with a one page read. This example is illustrated in FIG. 6B where data block 630 includes metadata 631, data block 632 includes metadata 633, data block 634 includes metadata 635, and data block 636 includes metadata 637.

Another advantage of this embodiment is that the approach will inherently recover all the data that is written on the non-volatile memory. This is due in part because this embodiment maps everything that can be read back, instead of relying on the timing of flushing table data using power hold up elements, such as capacitors.

Since table data is all written and read using the same path as the user data, all error handling and protection that is covered throughout that path applies to the table data as well. In some embodiments, this includes things such as read retries, and erasure protection.

In some embodiments, the ability to write a full snapshot of table data during runtime is utilized for power loss recovery, but this functionality can also be taken advantage of for program fail recovery. If a data block fails to successfully be written to the recovery region, a full snapshot can be written following the failure. This avoids having any holes in the table data, and avoids needing any complex garbage collection algorithm in order to migrate the valid table data left at risk due to the program fail.

Having a separate region for the table data also means that the recovery region can also utilize a less error prone flash mode (such as single level cell instead of triple level cell), and a more aggressive level of erasure protection, lowering the chance of ever losing any important table data.

Current solutions rely on physical scans that span a large amount of the block stripes in the array of non-volatile in order to recover block and block stripe states. These scans then have to map physical reads back to logical units. At the end of these scans, no mapping data has been recovered yet. To recover mapping data, large parts of the tables have to be frozen and written to non-volatile memory during runtime, which has negative effects on performance and QoS.

The writing of this table data also has its own path through the system, increasing the amount of firmware that has to be developed and maintained, with its own error handling and garbage collection algorithms, further complicating the system as a whole. The example embodiments discussed herein reduce the area of the array that has to be scanned by containing all media management table data in the recovery region, reduce the table data that has to be written during runtime, reduce firmware required by using the same read and write path for table data as user data, while also simplifying and reducing the scans themselves by using data block address offset based reads rather than physical page reads.

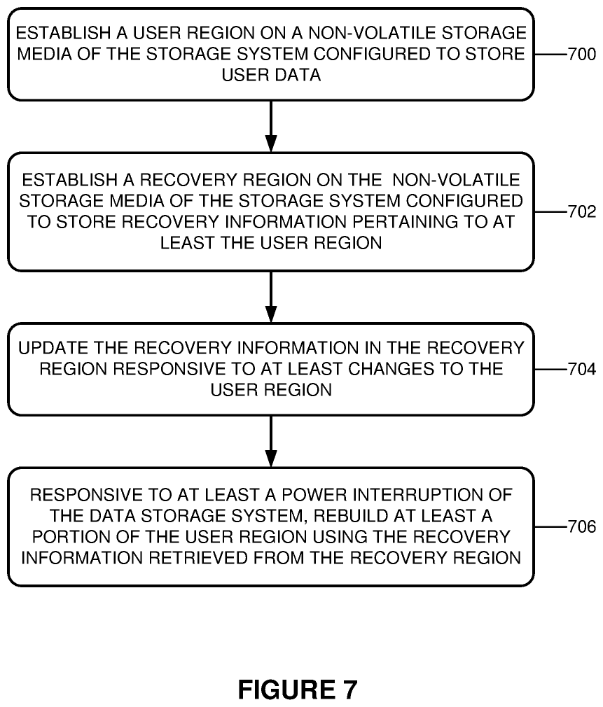

FIG. 7 illustrates an example method for power loss recovery. In this example, storage controller 210 establishes a user region 420 on a non-volatile storage media 230 of storage system 220 configured to store user data, (operation 700). Storage controller 210 also establishes a recovery region 410 on the non-volatile storage media 230 of storage system 220 configured to store recovery information pertaining to at least the user region 420, (operation 702).

Storage controller 210 updates the recovery information in the recovery region 410 responsive to at least changes in the user region 420, (operation 704). Responsive to at least a power interruption of the data storage system 220, storage controller 210 rebuilds at least a portion of user region 420 using the recovery information retrieved from recovery region 410, (operation 706).

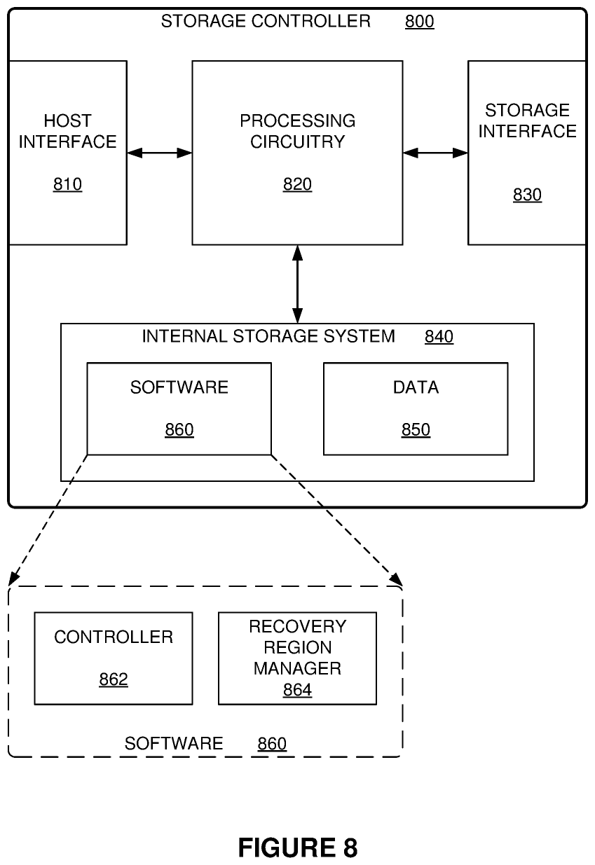

FIG. 8 illustrates storage controller 800, such as storage controller 210 from FIG. 2. As discussed above, storage controller 800 may take on any of a wide variety of configurations. Here, an example configuration is provided for a storage controller implemented as an ASIC. However, in other examples, storage controller 800 may be built into a storage system or storage array, or into a host system.

In this example embodiment, storage controller 800 comprises host interface 810, processing circuitry 820, storage interface 830, and internal storage system 840. Host interface 810 comprises circuitry configured to receive data and commands from an external host system and to send data to the host system.

Storage interface 830 comprises circuitry configured to send data and commands to an external storage system and to receive data from the storage system. In some embodiments storage interface 830 may include ONFI ports for communicating with the storage system.

Processing circuitry 820 comprises electronic circuitry configured to perform the tasks of a storage controller enabled to recover from a power interruption as described above. Processing circuitry 820 may comprise microprocessors and other circuitry that retrieves and executes software 860. Processing circuitry 820 may be embedded in a storage system in some embodiments. Examples of processing circuitry 820 include general purpose central processing units, application specific processors, and logic devices, as well as any other type of processing device, combinations, or variations thereof. Processing circuitry 820 can be implemented within a single processing device but can also be distributed across multiple processing devices or sub-systems that cooperate in executing program instructions.

Internal storage system 840 can comprise any non-transitory computer readable storage media capable of storing software 860 that is executable by processing circuitry 820. Internal storage system 820 can also include various data structures 850 which comprise one or more databases, tables, lists, or other data structures. Storage system 840 can include volatile and nonvolatile, removable and non-removable media implemented in any method or technology for storage of information, such as computer readable instructions, data structures, program modules, or other data.

Storage system 840 can be implemented as a single storage device but can also be implemented across multiple storage devices or sub-systems co-located or distributed relative to each other. Storage system 840 can comprise additional elements, such as a controller, capable of communicating with processing circuitry 820. Examples of storage media include random access memory, read only memory, magnetic disks, optical disks, flash memory, virtual memory and non-virtual memory, magnetic cassettes, magnetic tape, magnetic disk storage or other magnetic storage devices, or any other medium which can be used to store the desired information and that can be accessed by an instruction execution system, as well as any combination or variation thereof.

Software 860 can be implemented in program instructions and among other functions can, when executed by storage controller 800 in general or processing circuitry 820 in particular, direct storage controller 800, or processing circuitry 820, to operate as described herein for a storage controller. Software 860 can include additional processes, programs, or components, such as operating system software, database software, or application software. Software 860 can also comprise firmware or some other form of machine-readable processing instructions executable by elements of processing circuitry 820.

In at least one implementation, the program instructions can include controller module 862, and recovery region manager module 864. Controller module 862 includes instructions directing processing circuitry 820 to operate a storage device, such as flash memory, including translating commands, encoding data, decoding data, configuring data, and the like. Recovery region manager module 864 includes instructions directing processing circuitry 820 to manage recovery region 410 within non-volatile memory 400 and to utilize recovery tables within recovery region 410 to recover data within non-volatile memory 400 in the case of a power interruption to storage system 130.

In general, software 860 can, when loaded into processing circuitry 820 and executed, transform processing circuitry 820 overall from a general-purpose computing system into a special-purpose computing system customized to operate as described herein for a storage controller, among other operations. Encoding software 860 on internal storage system 840 can transform the physical structure of internal storage system 840. The specific transformation of the physical structure can depend on various factors in different implementations of this description. Examples of such factors can include, but are not limited to the technology used to implement the storage media of internal storage system 840 and whether the computer-storage media are characterized as primary or secondary storage.

For example, if the computer-storage media are implemented as semiconductor-based memory, software 860 can transform the physical state of the semiconductor memory when the program is encoded therein. For example, software 860 can transform the state of transistors, capacitors, or other discrete circuit elements constituting the semiconductor memory. A similar transformation can occur with respect to magnetic or optical media. Other transformations of physical media are possible without departing from the scope of the present description, with the foregoing examples provided only to facilitate this discussion.

The example embodiments illustrated herein provide for several advantages over current solutions. For example, a storage drive does not need to employ capacitor or battery hold up to rebuild tables. Scan times are minimized using appropriate sizing. For example, data block size can be selected in order to optimize the time needed to perform a scan of the user region to recover host management tables. Other solutions are limited due to the time needed to scan the user region to recover host management tables.

In the example embodiments illustrated herein, the data block size can be tuned to lessen the overall quantity of flash pages that need to be read during scans to recover host management tables. Moreover, the scans typically comprise logical scans instead of physical scans, leading to reduced complexity. The example embodiments illustrated herein also lead to simplicity in block stripe state rebuilding, and the ability to produce a ‘fresh’ operational start after unexpected power losses or program errors.

The included descriptions and figures depict specific embodiments to teach those skilled in the art how to make and use the best mode. For the purpose of teaching inventive principles, some conventional aspects have been simplified or omitted. Those skilled in the art will appreciate variations from these embodiments that fall within the scope of the invention. Those skilled in the art will also appreciate that the features described above may be combined in various ways to form multiple embodiments. As a result, the invention is not limited to the specific embodiments described above, but only by the claims and their equivalents.

What is claimed is:

1. A method of operating a data storage system, the method comprising:
establishing a user region on a non-volatile storage media of the data storage system configured to store user data;
establishing a recovery region on the non-volatile storage media of the data storage system configured to store recovery information pertaining to at least the user region;
updating the recovery information in the recovery region responsive to at least changes to the user region; and
responsive to at least a power interruption of the data storage system, rebuilding at least a portion of the user region using the recovery information retrieved from the recovery region.

2. The method of claim 1, wherein rebuilding at least the portion of the user region comprises:
performing a first recovery region scan to read a first data block address (DBA) offset of each block stripe of the recovery region;
determining if each block stripe of the recovery region holds valid recovery data;
performing a second recovery region scan of ones of the block stripes that hold the valid recovery data, and determining ordering among the valid recovery data; and
based on the ordering, retrieving media management tables and change logs updating the media management tables from the recovery region.

3. The method of claim 2, wherein the recovery information comprises snapshots of the media management tables for the user region and the change logs indicating changes to the media management tables.

4. The method of claim 3, wherein no changes to the media management tables for the user region are considered complete until the change logs have been successfully written.

5. The method of claim 3, wherein the media management tables include information correlating data block addresses to physical locations within the user region on the non-volatile storage media of the data storage system.

6. The method of claim 1, wherein the user region and the recovery region do not share any data blocks on the non-volatile storage media of the data storage system.

7. The method of claim 1, wherein data written to the recovery region the same media management layer as data written to the user region.

8. A storage controller for a storage system, comprising:
a host interface, configured to receive data for storage within the storage system, and to transmit data from the storage system to a host system;
a storage interface, configured to transmit data to the storage system, and to receive data from the storage system; and
processing circuitry coupled with the host interface and the storage interface, configured to:
establish a user region on a non-volatile storage media of the data storage system configured to store user data;
establish a recovery region on the non-volatile storage media of the data storage system configured to store recovery information pertaining to at least the user region;
update the recovery information in the recovery region responsive to at least changes to the user region; and
responsive to at least a power interruption of the data storage system, rebuild at least a portion of the user region using the recovery information retrieved from the recovery region.

9. The storage controller of claim 8, wherein the processing circuitry is configured to rebuild at least the portion of the user region by:
performing a first recovery region scan to read a first data block address (DBA) offset of each block stripe of the recovery region;
determining if each block stripe of the recovery region holds valid recovery data;
performing a second recovery region scan of ones of the block stripes that hold the valid recovery data, and determining ordering among the valid recovery data; and
based on the ordering, retrieving media management tables and change logs updating the media management tables from the recovery region.

10. The storage controller of claim 9, wherein the recovery information comprises snapshots of the media management tables for the user region and the change logs indicating changes to the media management tables.

11. The storage controller of claim 10, wherein no changes to the media management tables for the user region are considered complete until the change logs have been successfully written.

12. The storage controller of claim 10, wherein the media management tables include information correlating data block addresses to physical locations within the user region on the non-volatile storage media of the data storage system.

13. The storage controller of claim 8, wherein the user region and the recovery region do not share any data blocks on the non-volatile storage media of the data storage system.

14. The storage controller of claim 8, wherein data written to the recovery region the same media management layer as data written to the user region.

15. One or more non-transitory computer-readable media having stored thereon program instructions to operate a storage controller for a storage system, wherein the program instructions, when executed by processing circuitry, direct the processing circuitry to at least:
establish a user region on a non-volatile storage media of the data storage system configured to store user data;
establish a recovery region on the non-volatile storage media of the data storage system configured to store recovery information pertaining to at least the user region;
update the recovery information in the recovery region responsive to at least changes to the user region; and
responsive to at least a power interruption of the data storage system, rebuild at least a portion of the user region using the recovery information retrieved from the recovery region.

16. The one or more non-transitory computer-readable media of claim 15, wherein the program instructions, when executed by the processing circuitry, direct the processing circuitry to rebuild at least the portion of the user region by:
performing a first recovery region scan to read a first data block address (DBA) offset of each block stripe of the recovery region;
determining if each block stripe of the recovery region holds valid recovery data;
performing a second recovery region scan of ones of the block stripes that hold the valid recovery data, and determining ordering among the valid recovery data; and
based on the ordering, retrieving media management tables and change logs updating the media management tables from the recovery region.

17. The one or more non-transitory computer-readable media of claim 16, wherein the recovery information comprises snapshots of the media management tables for the user region and the change logs indicating changes to the media management tables.

18. The one or more non-transitory computer-readable media of claim 17, wherein no changes to the media management tables for the user region are considered complete until the change logs have been successfully written.

19. The one or more non-transitory computer-readable media of claim 17, wherein the media management tables include information correlating data block addresses to physical locations within the user region on the non-volatile storage media of the data storage system.

20. The one or more non-transitory computer-readable media of claim 15, wherein data written to the recovery region the same media management layer as data written to the user region.
